(19) United States
(12) Patent Application Publication
(10) Pub. No.: US 2010/0232121 A1
(43) Pub. Date: Sep. 16, 2010

(54) Interconnect for Printed Board Assembly

(76) Inventors: Glen C. Oliver, Arlington, TX (US); Thomas E. Byrd, Grand Prairie, TX (US); Alan L. Phillips, Burleson, TX (US); Charles Donald Dupriest, Arlington, TX (US); Samuel O. Polk, Arlington, TX (US)

Correspondence Address: DAVIS PATENT SERVICES, LLC, 9616 RAVENSWOOD RD., GRANBURY, TX, 76049, US

(21) Appl. No.: 12/675,488

(22) PCT Filed: Aug. 29, 2008
(86) PCT No.: PCT/US2008/074757

§ 371 Date: Feb. 26, 2010

Related U.S. Application Data
(60) Provisional application No. 60/969,069, filed on Aug. 30, 2007.

(51) Int. Cl. H05K 1/14; H05K 1/18; H05K 3/00

(52) U.S. Cl. 361/749; 174/260; 29/829

(57) ABSTRACT

A printed board includes a base printed board including a trace; an electronic component operably associated with the base printed board; and a dielectric connector build-up extending from the base printed board. The dielectric connector build-up defines a via. The printed board further includes a land attachment site disposed in the via. The land attachment site extends through the dielectric connector build-up and into the base printed board. The land attachment site is electrically coupled with the trace and is configured to be electrically coupled to another printed board by one of an electrically conductive compound and a flowed solder ball.

### TECHNICAL FIELD

The present invention relates to printed boards and assemblies of printed boards.

### DESCRIPTION OF THE PRIOR ART

Printed boards, such as, for example, printed wiring boards and printed circuit boards, are used in many modern devices and systems. The designs of such devices and systems, however, are becoming ever smaller with greater electronic functionality. As a result, printed boards and assemblies of printed boards must occupy ever smaller volumes in these devices and systems.

One way to reduce the volume occupied by printed boards is to use “fuzz button” connectors to electrically couple adjacent printed boards. Generally, a fuzz button connector comprises a single strand of wire compressed into a cylindrical shape. FIG. 1 depicts a conventional use of fuzz button connectors, wherein printed boards 101 and 103 are electrically coupled by fuzz button connectors 105 and 107. Fuzz button connectors, however, exhibit large footprints and, thus, limit the number of connections that can be made per unit area of a printed board. Moreover, fuzz button connectors require clamps or brackets to maintain electrical connection between printed boards via fuzz button connectors. For example, in FIG. 1, a clamp 109 is used to compress fuzz button connectors 105 and 107 to maintain electrical contact between printed boards 101 and 103 via fuzz button connectors 105 and 107.

Wires can be physically soldered or otherwise attached between printed boards to provide electrical pathways between the boards. For example, FIG. 2 depicts wires 201 and 203 electrically coupling printed boards 205 and 207. The use of wires to electrically interconnect printed boards, however, is labor intensive and, thus, costly in both time and money. Moreover, the wires extend beyond the edges of the printed boards, thus requiring the printed board assembly to occupy a larger volume than desired.

There are many designs of printed boards and printed board assemblies well known in the art; however, considerable shortcomings remain.

### BRIEF DESCRIPTION OF THE DRAWINGS

The novel features believed characteristic of the invention are set forth in the appended claims. However, the invention itself, as well as a preferred mode of use, and further objectives and advantages thereof, will best be understood by reference to the following detailed description when read in conjunction with the accompanying drawings, in which the leftmost significant digit(s) in the reference numerals denote(s) the first figure in which the respective reference numerals appear, wherein:

FIGS. 1 and 2 are stylized views of conventional printed board assemblies;

FIG. 3 is a perspective view of a first illustrative embodiment of a printed board;

FIGS. 4-6 are stylized, cross-sectional views of a portion of the printed board of FIG. 3 taken along the 4-4 line in FIG. 3;

FIG. 7 is a perspective view of a second illustrative embodiment of a printed board;

FIGS. 8-13 are perspective views illustrating one particular method of making the printed boards of FIG. 3 or 7;

FIGS. 14-16 are perspective views illustrating one particular method of making printed board assemblies; and

FIGS. 17-22 depict illustrative embodiments of edge connections between printed boards.

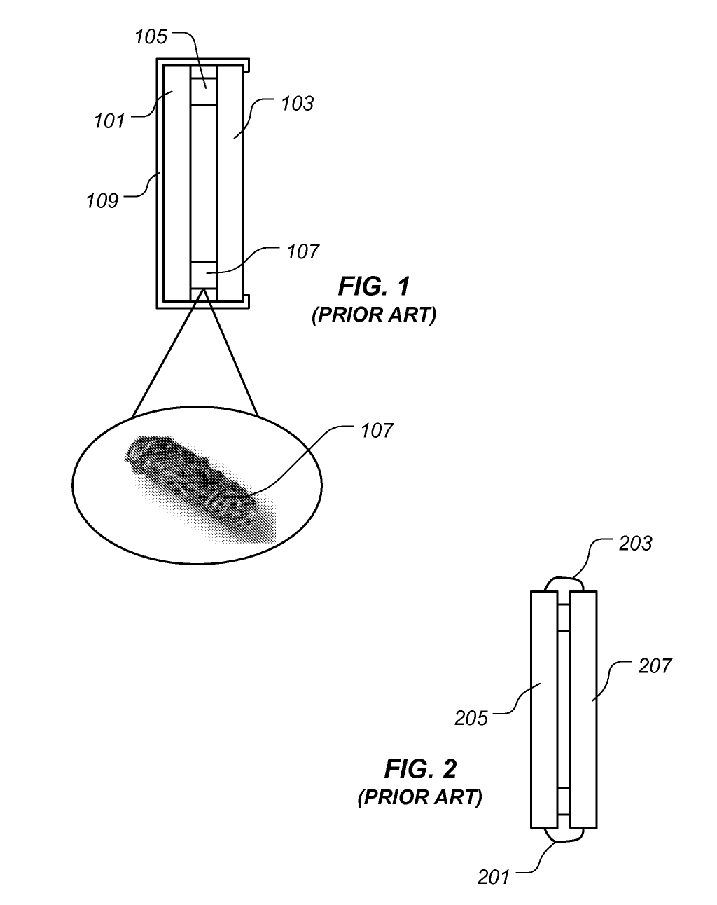

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DESCRIPTION OF THE PREFERRED EMBODIMENT

Illustrative embodiments of the invention are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

In the specification, reference may be made to the spatial relationships between various components and to the spatial orientation of various aspects of components as the devices are depicted in the attached drawings. However, as will be recognized by those skilled in the art after a complete reading of the present application, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

The present invention represents an electrical interconnect for a printed board assembly and a printed board, incorporating the electrical interconnect, that is configured to be assembled with similar printed boards into a substantially rigid stack and a method for making the printed board.

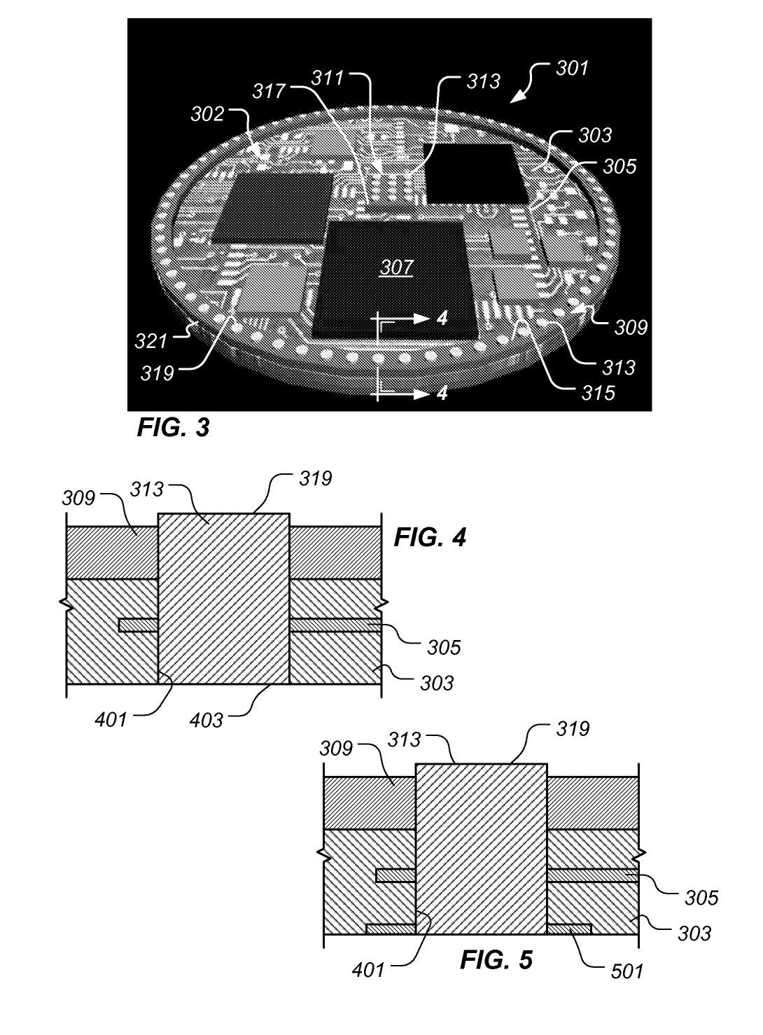

FIG. 3 depicts a first illustrative embodiment of a printed board 301. In the illustrated embodiment, printed board 301 includes a base printed board 302 comprising a dielectric base substrate 303 and one or more electrically conductive traces, such as a trace 305, disposed on or in substrate 303. One or more electronic components, such as an electronic component 307, are disposed on base substrate 303 and electrically coupled with one or more traces of printed board 301. Printed board 301 further comprises one or more dielectric connector build-ups, such as a first dielectric build-up 309 and a second dielectric build-up 311 of FIG. 3, extending from base substrate 303. Connector build-ups 309 and 311 can be integral with base substrate 303 or can be attached to base substrate 303, as is discussed in greater detail herein. Connector build-ups 309 and 311 extend to a height above substrate 303 that is greater than a height to which the one or more electronic components, such as electronic component 307, extends above substrate 303.

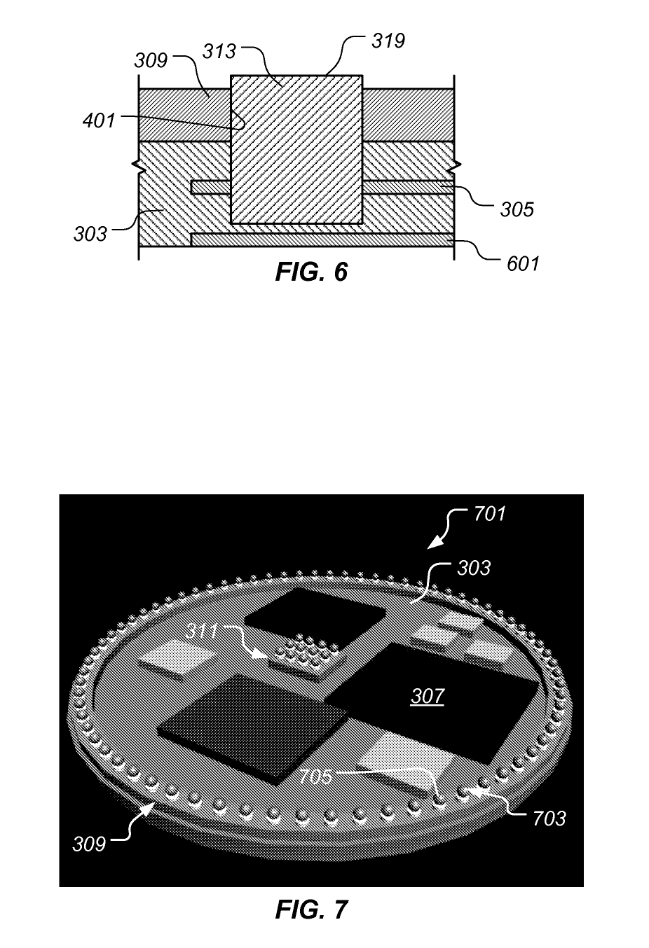

Still referring to FIG. 3, connector build-ups 309 and 311 each define one or more vias, such as via 401 of FIG. 4. One land attachment site 313 (only two labeled in FIG. 3 for clarity) is disposed through each of the vias into substrate 303, where each land attachment site is electrically coupled with one or more traces, such as trace 305. Preferably, land attachment sites 313 extend from upper surfaces 315 and 317 of connector build-ups 309 and 311, respectively. In the embodiment of FIG. 3, land attachment sites 313 are configured so that a solder paste or an electrically conductive adhesive can be placed on upper surfaces 319 thereof (only one labeled in FIG. 3 for clarity). The solder paste or electrically conductive adhesive is used to mechanically join adjacent printed boards, such as printed board 301, and to electrically couple land attachment sites 313 with corresponding land attachment sites or pads of an adjacent printed board, such as a lower surface 403 (shown in FIG. 4) of land attachment site 313 of an adjacent printed board, a pad 501 (shown in FIG. 5) electrically coupled with land attachment site 313 of an adjacent printed board, or a pad 601 (shown in FIG. 6) of an adjacent printed board.

It should be noted that printed board 301 may include clocking and/or alignment features to allow adjacent printed boards to be positioned correctly relative to one another or to allow assembled stacks of printed boards to be correctly positioned relative to other devices, equipment, systems, elements, and the like. Moreover, printed board 301 may include potting to protect interconnections between electronic components, such as electronic component 307, and the like and traces, such as trace 305.

In the embodiment illustrated in FIG. 3, printed board 301 and connector build-ups 309 and 311 are depicted as exhibiting particular shapes. Moreover, connector build-ups 309 and 311 are shown as being disposed at particular locations with respect to base substrate 303. The scope of the present invention, however, is not so limited. Rather, printed board 301 and connector build-ups 309 and 311 may exhibit any desired, suitable shape and size. Moreover, connector build-ups 309 and 311 may be located at any suitable location with respect to base substrate 303. Connector build-ups 309 and 311 may define any suitable number of vias, such as via 401 of FIG. 4, with corresponding land attachment sites 313. It should also be noted that land attachment sites 313 may be of any desired, suitable shape and size. The particular configurations of printed board 301 and the elements comprising printed board 301 are implementation specific and variations of these elements are contemplated by the present invention.

The scope of the present invention is not limited to configurations of printed boards that utilize solder paste or electrically conductive adhesive to mechanically join and electrically couple adjacent printed boards. FIG. 7 depicts a second, illustrative embodiment of a printed board 701 that corresponds to printed board 301 except that one or more land attachment sites 313 are replaced with land attachment sites 703 having solder balls 705. It should be noted that traces, such as trace 305 of FIG. 3, are not visible in the view of FIG. 7. Land attachment sites 703 extend through a via, such as via 401 of FIG. 4, into substrate 303, where each land attachment site 703 is electrically coupled with one or more traces, such as trace 305. After stacking one or more printed boards, such as printed board 701, the stacked assembly is heated to reflow the solder of solder balls 705 to mechanically join and electrically couple adjacent printed boards.

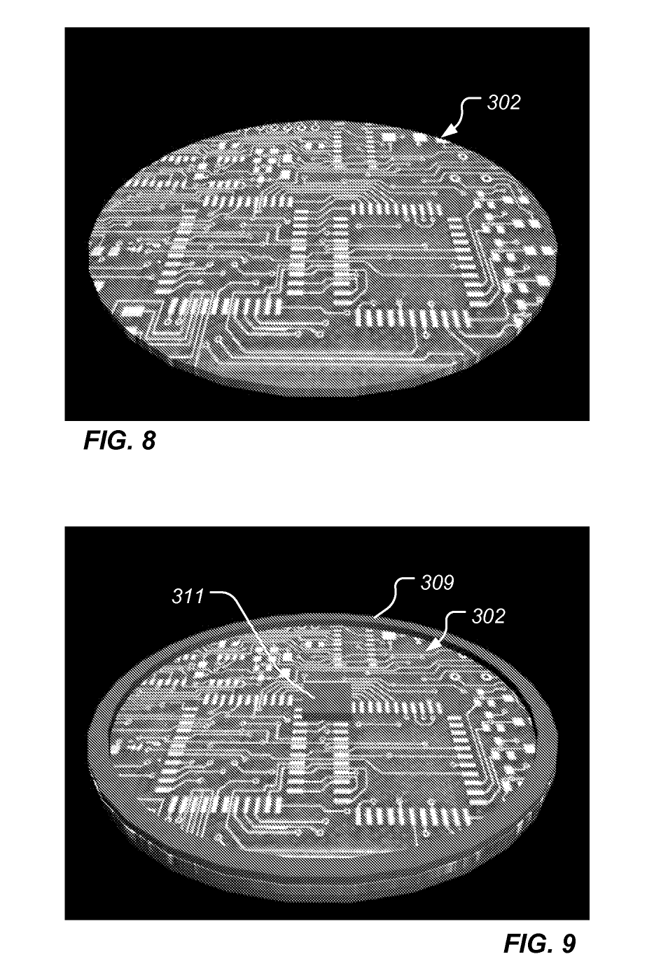

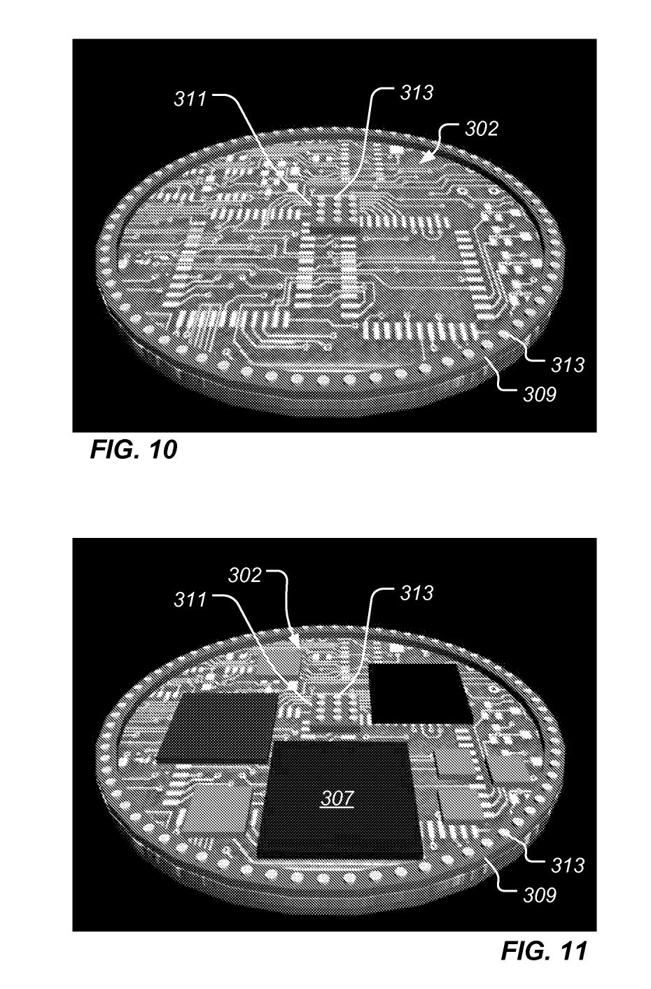

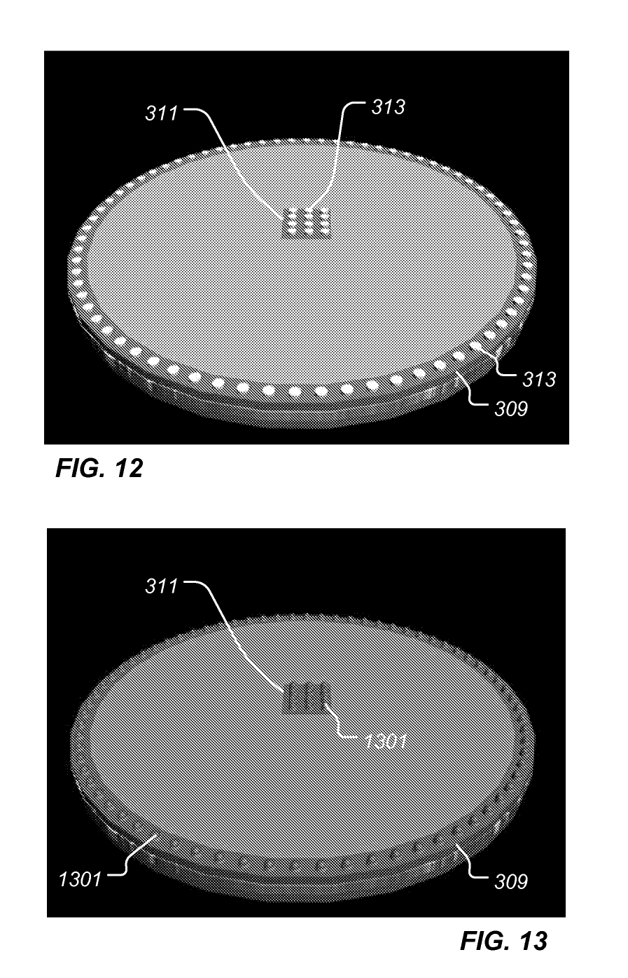

FIGS. 8-12 depict one particular embodiment of a method of making printed board 301. FIGS. 13-15 depict one particular embodiment of a method of making a stacked printed board assembly 1501 (shown in FIG. 15). Referring to FIG. 8, base printed board 302 is fabricated and provided. Turning to FIG. 9, build-ups 309 and 311 are attached to base printed board 302. Alternatively, as noted above, one or both of build-ups 309 and 311 are integral with base printed board 302. Referring now to FIG. 10, vias, such as via 401 of FIG. 4, are produced through build-ups 309 and 311 into base printed board 302 and the vias are filled with an electrically conductive material. In one embodiment, the vias are produced using a drilling process. It should be noted that, if build-up 309 or 311 is a separate component from base printed board 302, vias, such as via 401 of FIG. 4 may be produced and the vias filled with electrically conductive material (e.g., land attachment sites) to form an electrical interconnect prior to being assembled to base printed board 302. As shown in FIG. 11, printed board 301 is populated with electronic components, such as electronic component 307. In one embodiment, shown in FIG. 12, a potting material 1201 is disposed on base printed board 302 to protect the electronic components attached thereto, the interconnections between the electronic components and the traces, and the traces themselves. Preferably, potting material 1201 is applied such that only build-ups 309 and 311 protrude therethrough. As shown in FIG. 13, an electrically conductive compound 1301, such as a solder paste or electrically conductive adhesive, is applied to upper surfaces 319 of land attachment sites 313. Printed board 301 is ready to be assembled into a stack along with other printed boards.

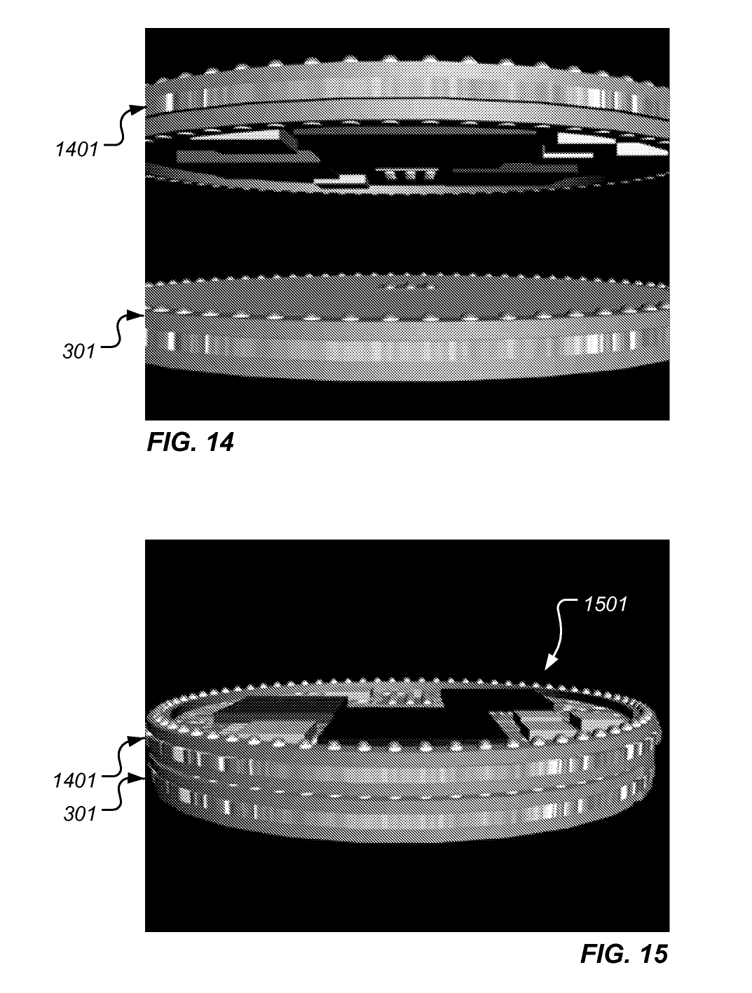

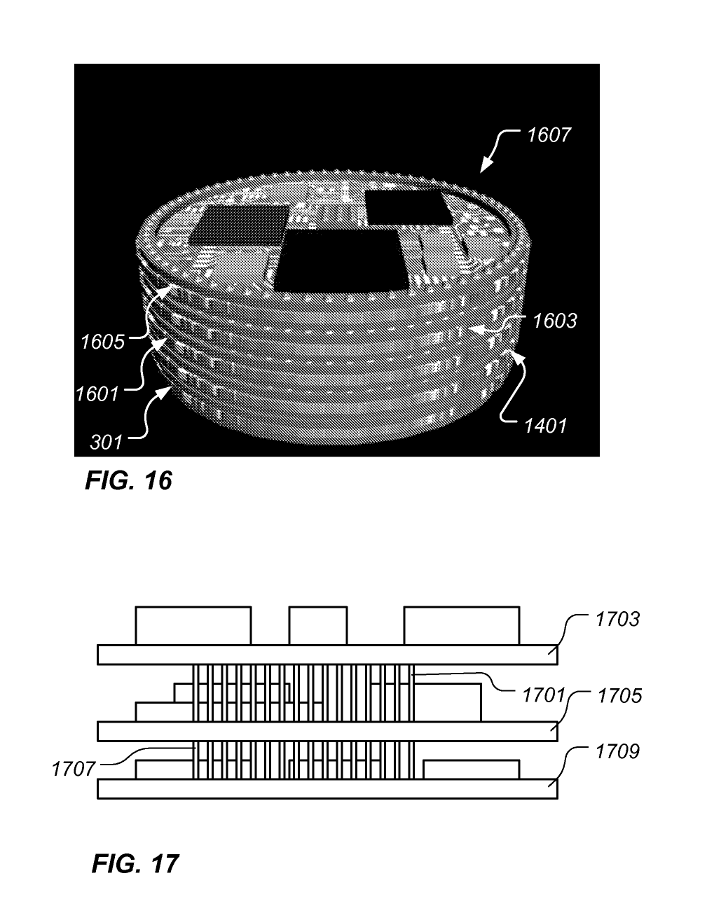

Referring now to FIGS. 14-16 and in particular to FIG. 15, a second printed board 1401 of the present invention is stacked onto printed board 301, as shown in FIG. 15, such that electrically conductive compound 1201 electrically couples land attachment sites 313 and the corresponding pads or land attachment sites of second printed board 1401 and mechanically joins printed boards 301 and 1401. Preferably stacking operations are conducted using automated equipment to inhibit human error and increase the spatial accuracy of printed board 301 with respect to printed board 1401. Turning to FIG. 16, one or more other printed boards 1601, 1603, and 1605 may be incrementally stacked onto second printed board 1401. It should be noted that any suitable, desirable number of printed boards may be mechanically joined in a stacked assembly. For example, in FIG. 15, printed boards 301 and 1401 form an assembly 1501. In another example, shown in FIG. 16, printed boards 301, 1401, 1601, 1603, and 1605 form an assembly 1607.

If an electrically conductive adhesive is used, the assembly is ready to use after sufficient time has elapsed for the electrically conductive adhesive to cure. In some implementations, heat may be applied to such assemblies to enhance the curing process. If a solder paste is used, the assembly is subjected to heat to reflow the solder paste, thus mechanically joining and electrically coupling adjacent printed boards.

It should be noted, however, that the methods illustrated in FIGS. 8-15 are applicable to an illustrative method of making printed board 701 and making a stacked printed board assembly comprising a plurality of printed boards that incorporate land attachment sites, such as printed board 701. If land attachment sites 703 are used in place of land attachment sites 313, as in printed board 701 (shown in FIG. 7), no electrically conductive compound is used, as land attachment sites 703 include solder balls 705. An assembly comprising printed board 701 and other printed boards of the present invention are subjected to heat to reflow the solder balls, thus mechanically joining and electrically coupling adjacent printed boards.

While land attachment sites 313 and 703 are effective as pathways for electrical signals between electrical components of printed boards in a printed board assembly, the scope of the present invention is not so limited. Rather, land attachment sites 313, in combination with a joining compound such as an adhesive, an electrically conductive adhesive, a solder paste, or the like, and/or land attachment sites 703 may be used with build-ups, such as build-ups 309 and 311, to provide structural support between printed boards, either alone or in combination with electrical coupling between printed boards. Moreover, portions of printed board 301 or 701 may be plated to provide electromagnetic shielding between sections of the printed board 301 or 701, such as between a radio-frequency section and a digital section. Electrical connection through land attachment sites 313 or 703 between ground planes of adjacent printed boards by such plating provides a faraday cage. In another embodiment, an outer edge 321 (shown in FIG. 3) may be plated an attached to chassis ground or maintained in an electrically isolated state to provide a faraday cage. It should also be noted that land attachment sites 313 and/or 703 may be used as a thermal passageway for removing heat from electronic components and the like.

It should also be noted that build-ups, such as build-ups, such as build-ups 309 and 311, may include electrically-conductive traces. For example, such build-ups may include traces that provide an output pattern therefrom that is different from an input pattern thereto.

The present invention contemplates other means for electrically interconnecting printed boards, such as printed boards 301, 1401, 1601, 1603, 1604, and the like, along edges of the printed boards. For example, as shown in FIG. 17, one or more solder columns 1701 (only one labeled for clarity) electrically interconnect printed board 1703 and printed board 1705. One or more solder columns 1707 (only one labeled for clarity) electrically interconnect printed board 1705 and printed board 1709.

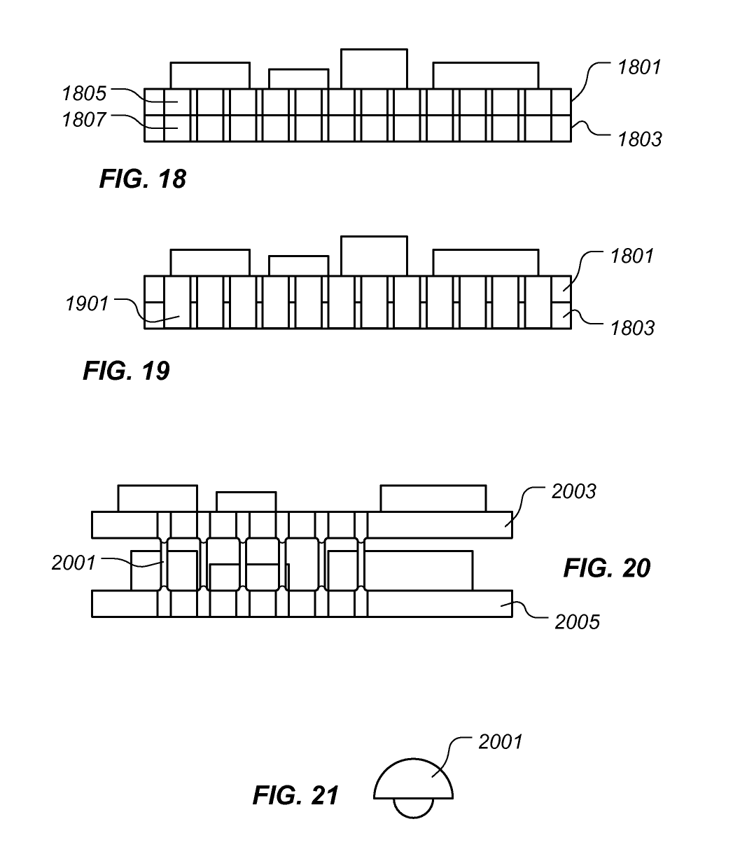

In another exemplary embodiment, shown in FIG. 18, edges of printed boards 1801 and 1803 are plated to produce one or more edge plated areas 1805 and 1807, respectively. Note that only one plated area 1805 and one plated area 1807 are labeled for clarity. Edge plated areas 1805 and 1807 are electrically coupled with one or more traces of their respective printed board 1801 or 1803. As shown in FIG. 19, an electrically conductive material 1901 (only one labeled for clarity), such as solder, electrically-conductive paint, or the like, electrically couples plated areas 1805 and 1807 of adjacent printed boards 1801 and 1803.

In yet another exemplary embodiment, shown in FIG. 20, one or more wires or pins 2001 (only one labeled for clarity) are soldered in half-barrel holes of printed boards 2003 and 2005 to electrically interconnect traces of printed boards 2003 and 2005. FIG. 21 depicts a top view of wire or pin 2001 to more clearly illustrate one particular configuration of wire or pin 2001.

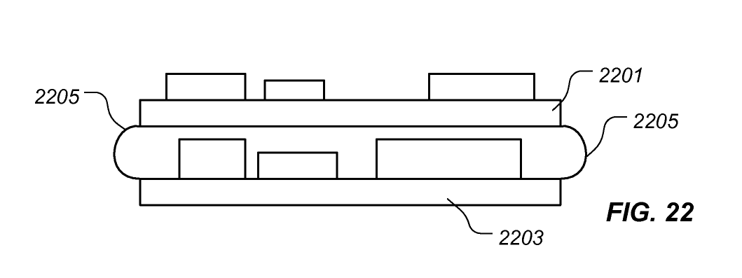

In another exemplary embodiment, shown in FIG. 22, traces of printed boards 2201 and 2203 are electrically interconnected by one or more flex circuits 2205.

It should be noted that the present invention contemplates employing any of the means for interconnecting printed boards disclosed herein or their equivalents and the means for interconnecting printed boards may be used in any combination.

The present invention provides significant advantages that include, but are not limited to, (1) providing a means for producing printed board assemblies that occupy a limited volume; and (2) providing a means for producing printed board assemblies that is cost and labor efficient.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below. It is apparent that an invention with significant advantages has been described and illustrated. Although the present invention is shown in a limited number of forms, it is not limited to just these forms, but is amenable to various changes and modifications without departing from the spirit thereof.

1. A printed board, comprising:
a base printed board including a trace;
an electronic component operably associated with the base printed board;
a dielectric connector build-up extending from the base printed board, the dielectric connector build-up defining a via;
a land attachment site disposed in the via, the land attachment site extending through the dielectric connector build-up and into the base printed board, the land attachment site being electrically coupled with the trace, the land attachment site being configured to be electrically coupled to another printed board by one of an electrically conductive compound and a flowed solder ball.

2. The printed board, according to claim 1, further comprising:
a potting material disposed on the base printed board about the at least one electronic component.

3. The printed board, according to claim 1, further comprising one of:
a solder column for electrically coupling a second trace of the base printed board to another printed board;
a plated area of the printed board or dielectric connector build-up coupling a second trace of the base printed board configured to be electrically coupled with a plated area of another printed board by an electrically conductive material;
a wire or pin for electrically coupling a second trace of the base printed board to another printed board; and
a flex circuit for electrically coupling a second trace of the base printed board to another printed board.

4. A method of making a printed board, comprising:
providing a base printed board having a dielectric connector build-up;
generating a via through the dielectric connector build-up into the base printed board intersecting a trace of the base printed board;
filling the via with an electrically conductive land attachment site;
populating the base printed board with an electronic component; and
applying an electrically conductive compound to an upper surface of the electrically conductive land attachment site for mechanically joining the printed board to an adjacent printed board.

5. The method, according to claim 4, wherein providing the base printed board having the at least one dielectric connector build-up is accomplished by:
providing the base printed board; and
attaching the at least one dielectric connector build-up to the base printed board.

6. The method, according to claim 4, wherein providing the base printed board having the at least one dielectric connector build-up is accomplished by:
providing the base printed board having at least one integral dielectric connector build-up.

7. The method, according to claim 4, further comprising:
applying a potting material to the base printed board about the at least one electronic component.

8. A method of making a printed board, comprising:
providing a base printed board having a dielectric connector build-up;
generating a via through the dielectric connector build-up into the base printed board intersecting a trace of the base printed board;
filling the via with an electrically conductive land attachment site; and
populating the base printed board with an electronic component.

9. The method, according to claim 8, wherein providing the base printed board having the dielectric connector build-up is accomplished by:
providing the base printed board; and
attaching the dielectric connector build-up to the base printed board.

10. The method, according to claim 8, wherein providing the base printed board having the dielectric connector build-up is accomplished by:
providing the base printed board, such that the dielectric connector build-up is an integral dielectric connector build-up.

11. The method, according to claim 8, further comprising:
applying a potting material to the base printed board about the electronic component.

12. A method of making a printed board assembly, comprising:
providing a first printed board and a second printed board, the first printed board and the second printed board each comprising:
a base printed board including a trace;
an electronic component operably associated with the base printed board;
a dielectric connector build-up extending from the base printed board, the dielectric connector build-up defining a via;
a land attachment site disposed in the a via, the a land attachment site extending through the a dielectric connector build-up and into the base printed board, the a land attachment site being electrically coupled with the trace; and
mechanically joining and electrically coupling the first printed board and the second printed board by attaching the land attachment site of the first printed board to the land attachment site of the second printed board.

13. The method, according to claim 12, wherein mechanically and electrically coupling the first printed board and the second printed board is accomplished by:
applying an electrically conductive compound to the land attachment site; and
mating the second printed board to the first printed board.

14. The method, according to claim 13, further comprising:
heating the printed board assembly.

15. The method, according to claim 12, wherein the land attachment site includes a solder ball and mechanically and electrically coupling the first printed board and the second printed board is accomplished by:
mating the second printed board to the first printed board; and
heating the printed board assembly.

16. The method, according to claim 12, wherein mechanically joining and electrically coupling the first printed board and the second printed board is accomplished by one of:
providing a solder column electrically coupling the first printed board and the second printed board;
plating edge areas of the first and second printed boards and applying an electrically conductive material to the plated areas;
providing a wire or pin electrically coupling the first printed board and the second printed board; and
providing a flex circuit electrically coupling the first printed board and the second printed board.

17. An electrical interconnect for a printed board, comprising:
a dielectric connector build-up configured to extend from the printed board, the dielectric connector build-up defining a via;
a land attachment site disposed in the via, the land attachment site extending through the dielectric connector build-up and configured to extend into the printed board such that the land attachment site is electrically coupled with a trace of the printed board, the land attachment site being configured to be electrically coupled by an electrically conductive compound or a flowed solder ball to another printed board.
